(19) United States
(12) Patent Application Publication
(10) Pub. No.: US 2026/0317162 A1
(43) Pub. Date: Oct. 15, 2026

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventors: RANGANATHAN NAGARAJAN, Singapore (SG); ROHIT PULIKKAL KIZHAKKEYIL, Singapore (SG); RAMACHANDRAMURTHY PRADEEP YELEHANKA, Singapore (SG)

(73) Assignee: Vanguard International Semiconductor Corporation, Hsinchu (TW)

(21) Appl. No.: 19/176,189

(22) Filed: Apr. 11, 2025

(51) Int. Cl. B81C 1/00; B81B 3/00

(52) U.S. Cl. CPC B81C 1/00952; B81B 3/0008; B81B 2201/0235; B81B 2201/0242; B81B 2207/012; B81B 2207/07; B81B 2207/092; B81C 2201/112; B81C 2203/035; B81C 2203/0792

(57) ABSTRACT

A MEMS package includes a first substrate, an interconnect layer, a passivation layer, a first bonding layer, a device layer, a stand-off structure, a second bonding layer, and a second substrate. The interconnect layer is disposed on the first substrate and includes a top metal layer with a seal ring. The passivation layer is disposed on the top metal layer and has an opening to expose the seal ring. The first bonding layer is disposed on the seal ring. The device layer includes a MEMS device and is disposed above the interconnect layer. The stand-off structure is disposed under the device layer and surrounds the MEMS device. The second bonding layer is disposed under the stand-off structure and in direct contact with the first bonding layer. The second substrate includes a cavity and is bonded to the device layer.

### BACKGROUND OF THE INVENTION

The present disclosure relates generally to micro-electro-mechanical system (MEMS) technology, and more particularly to MEMS packages that include a bonding structure to improve the quality of the MEMS packages, and fabrication methods thereof.

### DESCRIPTION OF THE PRIOR ART

Micro-electro-mechanical system (MEMS) devices are microscopic devices that integrate mechanical and electrical components to sense physical quantities and/or to interact with the surrounding environment. MEMS devices, such as accelerometers, gyroscopes, pressure sensors, and microphones, have become widespread in many electronic products, for example, tablet computers, automobiles, and smartphones. A MEMS wafer is usually bonded to an aluminum (Al) layer on an interconnect wafer. Before bonding, the Al layer must be pre-cleaned with plasma to remove the native oxide. However, the plasma pre-clean process causes stiction due to the dielectric charging effect and also lowers the vacuum within the MEMS device. Therefore, conventional MEMS packages still have some issues that need to be overcome.

### SUMMARY OF THE INVENTION

In view of this, the present disclosure provides a micro-electro-mechanical system (MEMS) package and a fabrication method thereof to overcome the aforementioned issues. The MEMS package includes a bonding layer on a seal ring of an interconnect wafer. This bonding layer protects the seal ring from native oxide growth. The fabrication of the MEMS package does not require a plasma pre-clean process on the interconnect wafer, thereby preventing issues caused by the plasma pre-clean process.

According to an embodiment of the present disclosure, a MEMS package is provided and includes a first substrate, an interconnect layer, a passivation layer, a first bonding layer, a device layer, a stand-off structure, a second bonding layer, and a second substrate. The interconnect layer is disposed on the first substrate and includes a top metal layer with a seal ring. The passivation layer is disposed on the top metal layer and has an opening to expose the seal ring. The first bonding layer is disposed on the seal ring. The device layer includes a MEMS device and is disposed above the interconnect layer. The stand-off structure is disposed under the device layer and surrounds the MEMS device. The second bonding layer is disposed under the stand-off structure and in direct contact with the first bonding layer. The second substrate includes a cavity and is bonded to the device layer.

According to an embodiment of the present disclosure, a method of fabricating a micro-electro-mechanical system (MEMS) package is provided and includes the following steps. A first substrate is provided, and an interconnect layer is formed on the first substrate. The interconnect layer includes a top metal layer with a seal ring. A passivation layer is formed on the top metal layer and has an opening to expose the seal ring. A first bonding layer is formed on the seal ring. A second substrate is provided, and a cavity is formed in the second substrate. A device layer is formed on the second substrate to cover the cavity. A stand-off structure is formed to be integrated with the device layer. A second bonding layer is formed on the stand-off structure. The device layer is patterned to form a MEMS device, and the stand-off structure surrounds the MEMS device. In addition, the stand-off structure is bonded to the seal ring through the first bonding layer and the second bonding layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to an embodiment of the present disclosure.

FIG. 2 shows several schematic cross-sectional views of a partial area A in the MEMS package of FIG. 1 according to some embodiments of the present disclosure.

FIG. 3, FIG. 4, FIG. 5, FIG. 6, FIG. 7, FIGS. 8 and FIG. 9 are schematic cross-sectional views of some stages of a method for fabricating a MEMS package according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. For example, if the structure in the figures is turned over, elements described as "below" and/or "under" other elements or features would then be oriented "above" and/or "over" the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as "first", "second", and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms "coupled to" and "electrically connected to" include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages that include a bonding layer on the seal ring of a top metal layer of an interconnect wafer. Before bonding a MEMS wafer to the interconnect wafer, this bonding layer protects the seal ring from native oxide growth. Therefore, the interconnect wafer does not require a plasma pre-clean process to remove native oxide from the seal ring. This avoids stiction caused by the dielectric charging effect of the plasma pre-clean process. Moreover, it also avoids plasma ions being trapped in the interconnect wafer and subsequent outgassing during or after the MEMS wafer is bonded to the interconnect wafer, thereby preventing a reduction in the vacuum within the MEMS device. Therefore, the performance, reliability, and quality of the MEMS packages are improved.

Furthermore, before bonding the MEMS wafer to the interconnect wafer, the bonding layer on the seal ring is pre-cleaned using a wet pre-clean process to remove the native oxide thereon. This wet pre-clean process is a low-cost, high-throughput batch process, thereby enhancing the production yield of the MEMS packages.

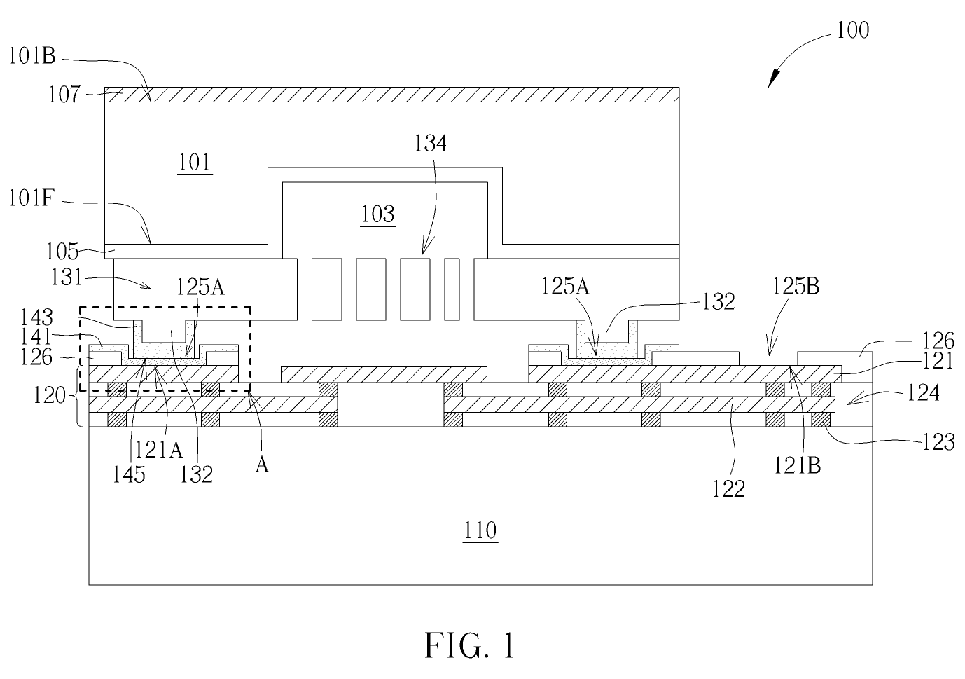

FIG. 1 is a schematic cross-sectional view of a MEMS package 100 according to an embodiment of the present disclosure. The MEMS package 100 includes a first substrate 110, an interconnect layer 120, a passivation layer 126, a first bonding layer 141, a device layer 131, a stand-off structure 132, a second bonding layer 143, and a second substrate 101. The first substrate 110 may be a silicon wafer and includes multiple CMOS transistors or other elements formed therein. The interconnect layer 120 is disposed on the first substrate 110. The interconnect layer 120 includes multiple metal layers such as a top metal layer 121 and a second-to-last metal layer 122, multiple dielectric layers 124, and multiple conductive vias 123 in these dielectric layers 124. The top metal layer 121 includes a seal ring 121A and a bond pad 121B. In some embodiments, the top metal layer 121 and the second-to-last metal layer 122 may be aluminum (Al) or aluminum copper alloy (AlCu) layers. The composition of the seal ring 121A and the bond pad 121B includes aluminum (Al). The dielectric layers 124 include an inter-metal dielectric (IMD) layer and an inter-layer dielectric (ILD) layer. The dielectric layers 124 may be silicon oxide layers.

Some conductive vias 123 electrically connect the top metal layer 121 to the second-to-last metal layer 122. Other conductive vias 123 electrically connect the second-to-last metal layer 122 to the CMOS transistors or other elements in the first substrate 110. The interconnect layer 120 is thereby electrically coupled to the CMOS transistors or other elements in the first substrate 110. The interconnect layer 120 and the first substrate 110 together may be referred to as a CMOS/interconnect wafer. In addition, the passivation layer 126 is disposed on the interconnect layer 120. The passivation layer 126 has an opening 125A to expose the seal ring 121A and another opening 125B to expose the bond pad 121B. The passivation layer 126 may be a silicon nitride layer. The first bonding layer 141 is disposed on the seal ring 121A and in the opening 125A of the passivation layer 126, completely covering the portion of the seal ring 121A exposed from the opening 125A. Moreover, the first bonding layer 141 is in direct contact with the seal ring 121A.

The device layer 131 is disposed above the interconnect layer 120 and includes a MEMS device 134. The device layer 131 includes features such as trenches, cantilever beams, membranes, and proof masses to construct the MEMS device 134, for example, an accelerometer, a gyroscope, an inertial measurement unit (IMU) device, and/or other MEMS device. The stand-off structure 132 is a bond ring protruding towards the interconnect layer 120. The stand-off structure 132 is disposed under the device layer 131 and surrounds the MEMS device 134. Moreover, the stand-off structure 132 is integrated with the device layer 131 and has the same composition as the device layer 131. In some embodiments, the composition of the device layer 131 and the stand-off structure 132 may be doped silicon or doped polysilicon. The second bonding layer 143 is disposed under the stand-off structure 132 and surrounds the sidewalls of the stand-off structure 132. The device layer 131 is bonded to the interconnect layer 120 through the stand-off structure 132, the second bonding layer 143, and the first bonding layer 141 to provide a hermetic seal for the MEMS device 134. The second bonding layer 143 is in direct contact with the first bonding layer 141.

In some embodiments, the seal ring 121A includes aluminum (Al). The first bonding layer 141 on the seal ring 121A includes germanium (Ge). The second bonding layer 143 around the stand-off structure 132 includes germanium (Ge). Moreover, the second bonding layer 143 is thicker than the first bonding layer 141. For example, the thickness of the first bonding layer 141 may be about 50 nm to about 100 nm. The thickness of the second bonding layer 143 may be about 2 to 5 times that of the first bonding layer 141, but not limited thereto. After the stand-off structure 132 is bonded to the seal ring 121A by a eutectic bonding process, a eutectic bonding interface 145 is formed between the first bonding layer 141 and the second bonding layer 143. During and after the eutectic bonding process, the Al of the seal ring 121A and the Ge of the first bonding layer 141 form an aluminum-germanium alloy (AlGe) in the portion of the first bonding layer 141 directly contacting the seal ring 121A during the eutectic bonding process. Therefore, the eutectic bonding interface 145 is composed of AlGe from the first bonding layer 141 and Ge from the second bonding layer 143. Furthermore, the bonding temperature of the eutectic bonding process allows inter-diffusion of the Al of the seal ring 121A and the Ge of both the first bonding layer 141 and the second bonding layer 143 to form AlGe alloy at the eutectic bonding interface 145. Consequently, the quality of the eutectic bonding between the stand-off structure 132 and the seal ring 121A is improved.

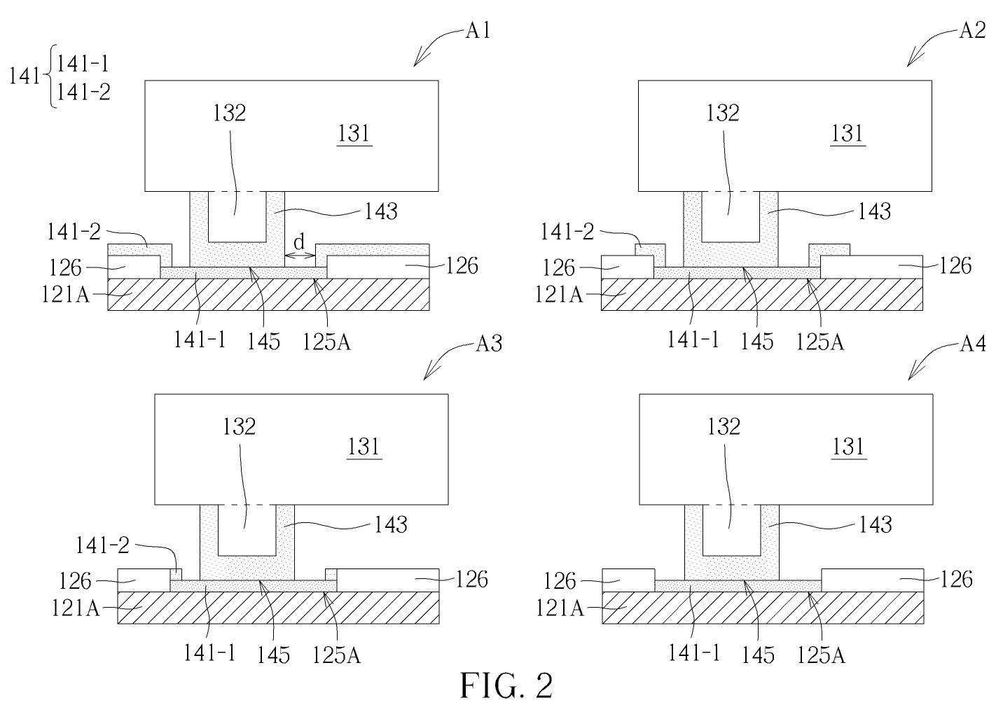

FIG. 2 shows several schematic cross-sectional views A1, A2, A3 and A4 of a partial area A in the MEMS package 100 of FIG. 1 according to some embodiments of the present disclosure. As shown in the cross-sectional view A1, in one embodiment, the first bonding layer 141 includes a first portion 141-1 and a second portion 141-2. The first portion 141-1 is in direct contact with the seal ring 121A. The composition of the first portion 141-1 includes germanium (Ge) of the first bonding layer 141 over aluminum (Al) of the seal ring 121A. The second portion 141-2 is in direct contact with the passivation layer 126. The first bonding layer 141 is disposed in the opening 125A of the passivation layer 126, and extends onto the sidewalls of the opening 125A and the top surface of the passivation layer 126. In this embodiment, the first bonding layer 141 is aligned with the outer sidewall of the passivation layer 126. Furthermore, after the stand-off structure 132 is bonded to the seal ring 121A by eutectic bonding, the composition of the first portion 141-1 includes AlGe, and the composition of the second portion 141-2 includes Ge. The composition of the second bonding layer 143 around the stand-off structure 132 includes Ge. The eutectic bonding interface 145 between the first bonding layer 141 and the second bonding layer 143 is composed of AlGe alloy after inter-diffusion of Al and Ge during the eutectic bonding process.

In addition, as shown in the cross-sectional view A1, the second bonding layer 143 includes a portion conformally disposed on the sidewall of the stand-off structure 132. The second portion 141-2 of the first bonding layer 141 includes a portion conformally disposed on the sidewall of the opening 125A of the passivation layer 126. The portion of the second bonding layer 143 is laterally separated from the portion of the first bonding layer 141 by a distance d, for example, at least about 5 µm.

In another embodiment, as shown in the cross-sectional view A2, the second portion 141-2 of the first bonding layer 141 extends onto a partial top surface of the passivation layer 126, but is not aligned with the outer sidewalls of the passivation layer 126. In a further embodiment, as shown in the cross-sectional view A3, the second portion 141-2 of the first bonding layer 141 extends onto the sidewalls of the opening 125A of the passivation layer 126, but does not extend onto the top surface of the passivation layer 126. In yet another embodiment, as shown in the cross-sectional view A4, the first bonding layer 141 includes the first portion 141-1, without the second portion 141-2. The first bonding layer 141 of this embodiment is disposed within the opening 125A of the passivation layer 126, and does not extend onto the passivation layer 126. In these embodiments of the cross-sectional views A2, A3 and A4, the eutectic bonding interfaces 145 between the first bonding layer 141 and the second bonding layer 143 are composed of AlGe, where the Ge eventually becomes AlGe alloy after the eutectic bonding process.

According to embodiments of the present disclosure, the portion of the seal ring 121A exposed from the opening 125A of the passivation layer 126 is completely covered by the deposited material of the first bonding layer 141 before bonding the stand-off structure 132 to the seal ring 121A, thereby preventing native oxide growth on the seal ring 121A. The interconnect layer 120 does not require a plasma pre-clean process to remove native oxide on the seal ring 121A. This avoids stiction caused by the dielectric charging effect of the plasma pre-clean process. It also avoids lowering the vacuum within the MEMS device 134 caused by plasma ions trapped in the dielectric layers of the interconnect layer 120 and subsequently outgassing during and after bonding the device layer 131 to the interconnect layer 120. Furthermore, omitting the plasma pre-clean process enhances the production yield of the MEMS package 100.

In addition, referring to FIG. 1 again, the second substrate 101 is bonded to the device layer 131 through a liner oxide layer 105, for example, a silicon oxide layer. The second substrate 101 may be a silicon wafer, and may be referred to as a cap wafer. The second substrate 101 has a front side 101F opposite to a back side 101B. The cavity 103 is formed in the second substrate 101, near the front side 101F, and located directly above the MEMS device 134. The liner oxide layer 105 is disposed between the device layer 131 and the second substrate 101, and further conformally extends into the cavity 103. Furthermore, a metal layer 107 is disposed on the back side 101B of the second substrate 101. The metal layer 107 is provided for radio frequency (RF) shielding and/or grounding. The metal layer 107 may be electrically connected to the bond pad 121B of the top metal layer 121, such that the bond pad 121B is configured to be connected to a ground voltage.

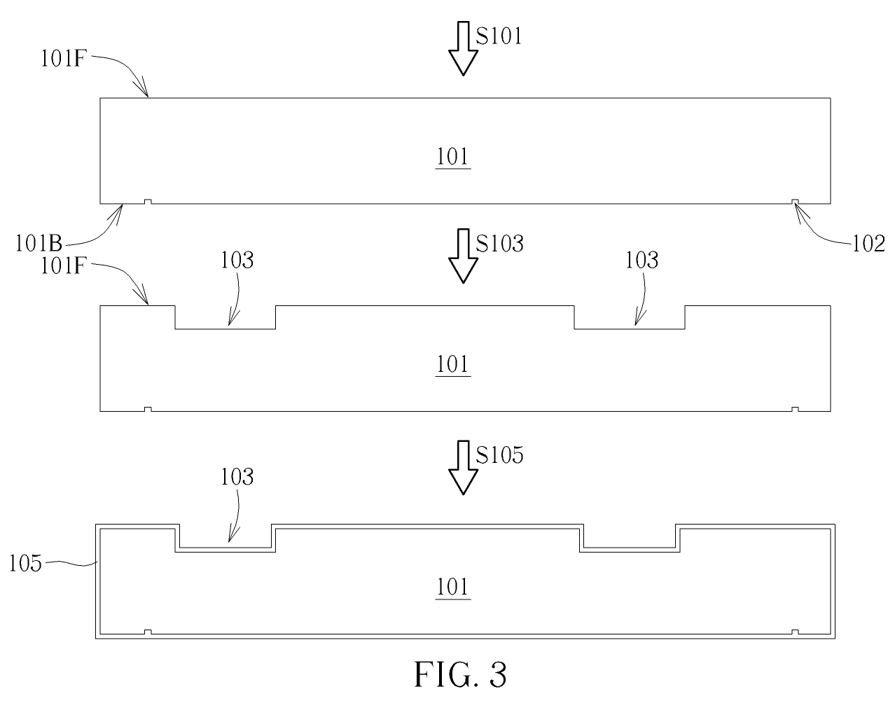

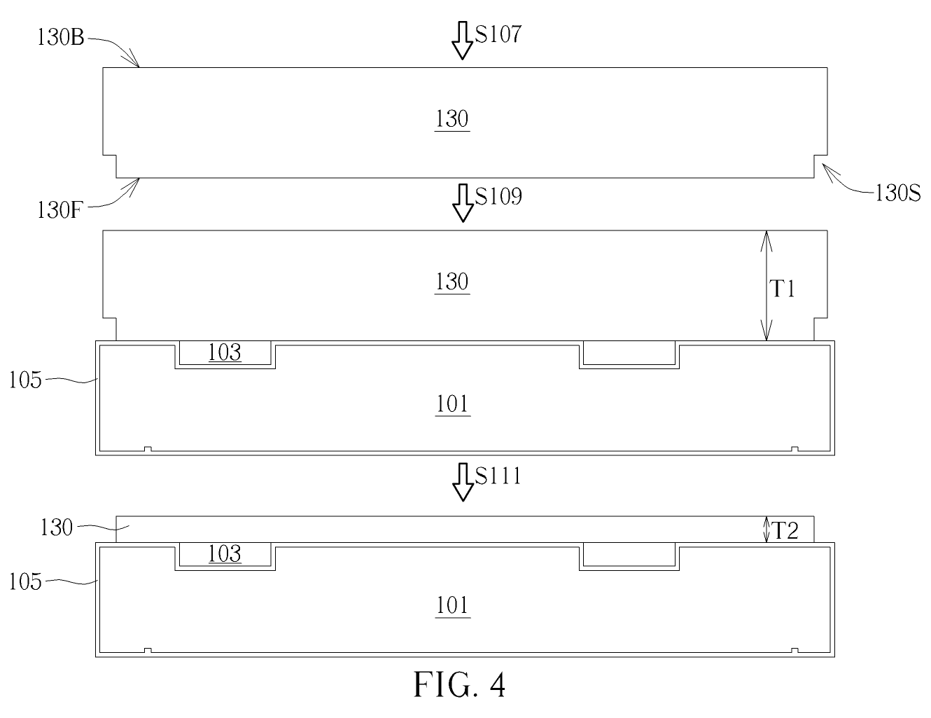

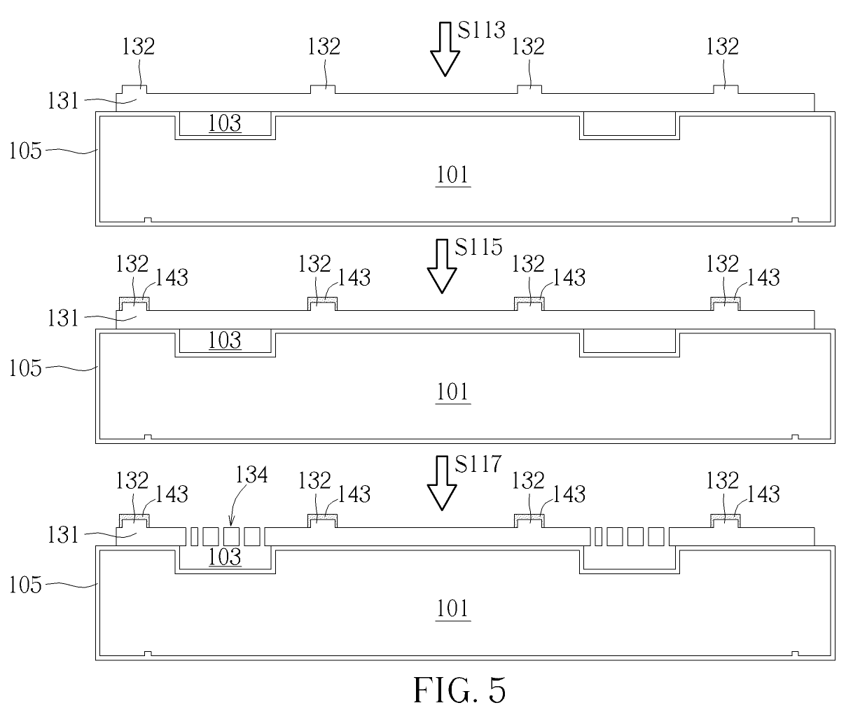

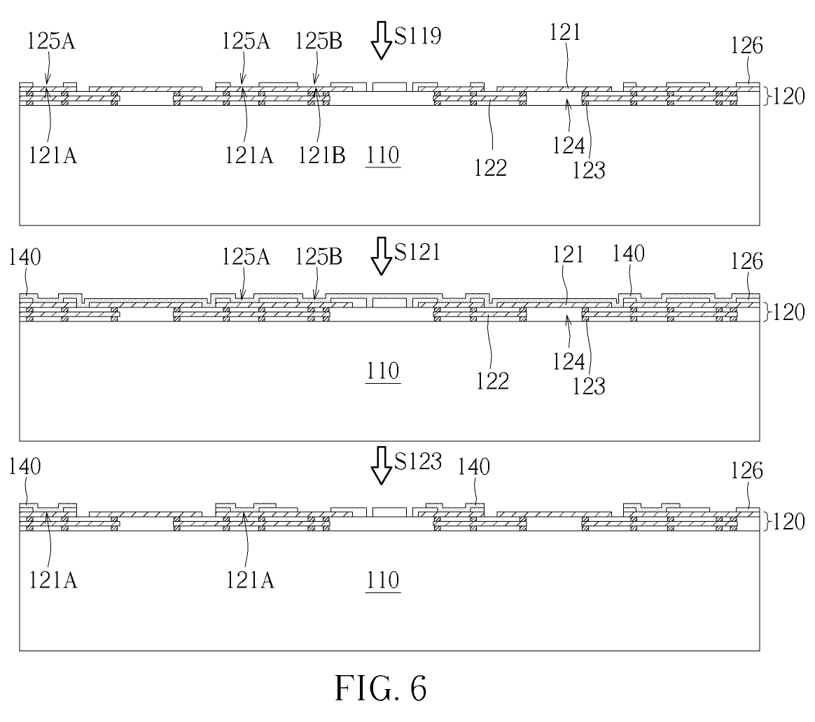

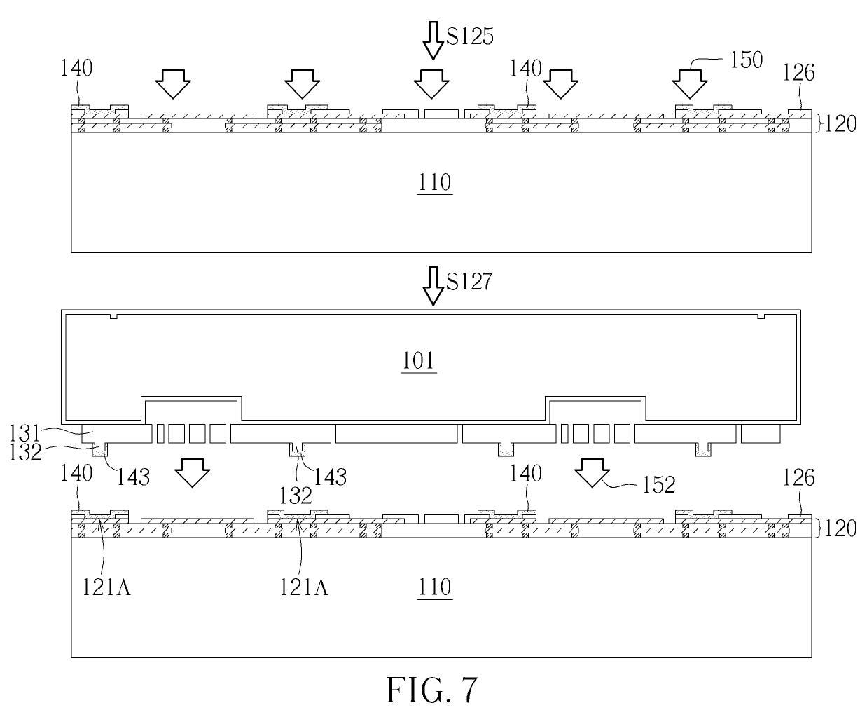

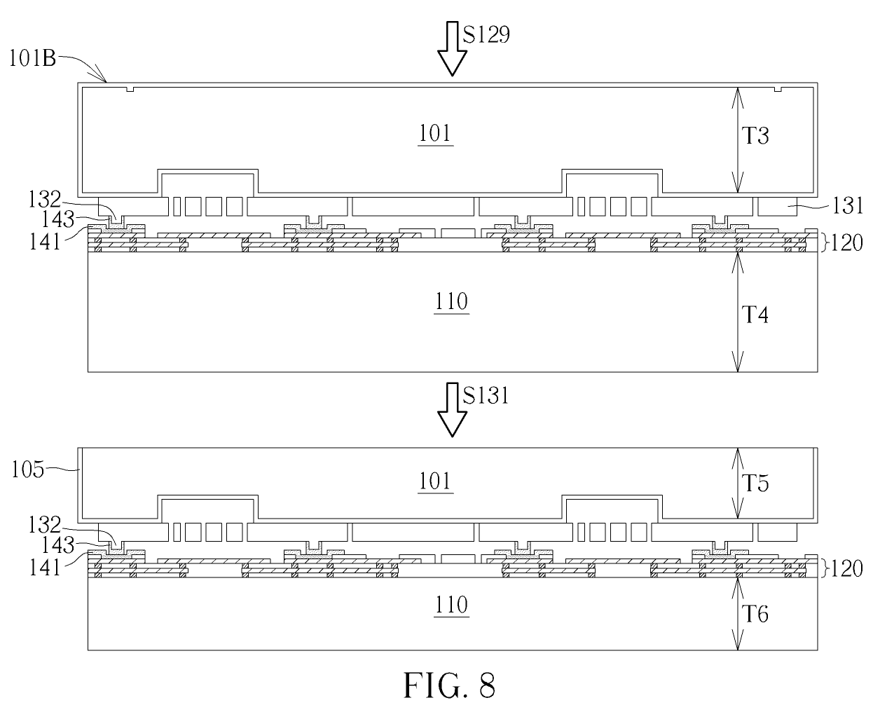

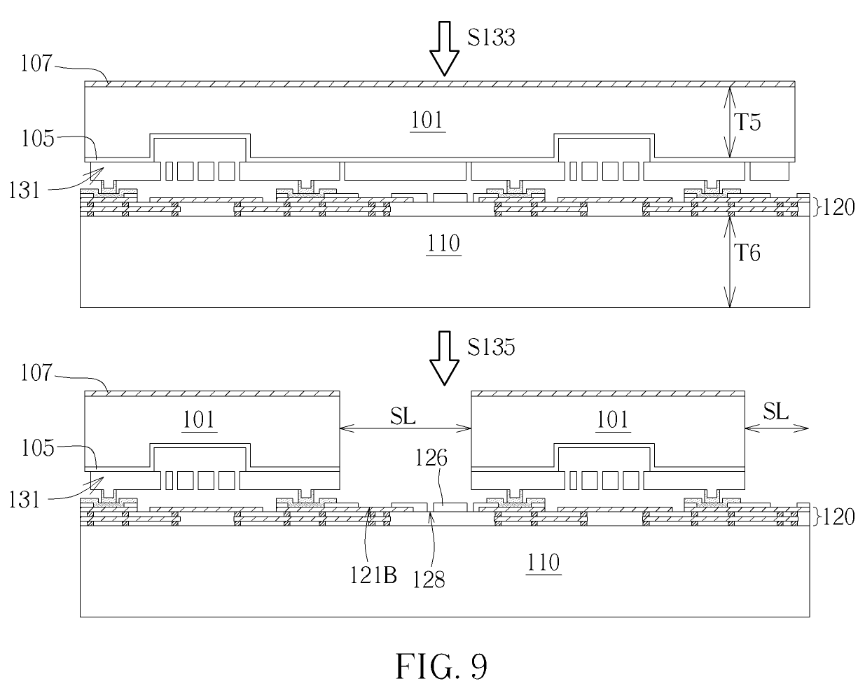

FIG. 3, FIG. 4, FIG. 5, FIG. 6, FIG. 7, FIGS. 8 and FIG. 9 are schematic cross-sectional views of some stages of a method for fabricating a MEMS package 100 according to an embodiment of the present disclosure. Referring to FIG. 3, in step S101, a second substrate 101 such as a silicon wafer is provided as a handle wafer or a cap wafer. The second substrate 101 is polished on both the front side 101F and the back side 101B. Multiple alignment marks 102 are formed on the back side 101B of the second substrate 101 by patterning and etching. Next, in step S103, multiple cavities 103 are formed at the front side 101F of the second substrate 101 by patterning and etching. The depth of these cavities 103 is, for example, about 20 µm, but is not limited thereto. Then, in step S105, a liner oxide layer 105 is conformally formed on the second substrate 101, extending into the cavities 103 to wrap around the second substrate 101. The liner oxide layer 105 is, for example, a silicon oxide layer, and may be formed by thermal oxidation. The thickness of the liner oxide layer 105 may be about 1.1 µm.

Next, referring to FIG. 4, in step S107, a device wafer 130 such as a silicon wafer is provided and polished on its front side 130F. The device wafer 130 may be heavily doped with boron to achieve a resistivity of about 0.008 ohm·cm to about 0.02 ohm·cm. Then, the device wafer 130 is trimmed at its edges 130S on the front side 130F. Afterwards, in step S109, the front side 130F of the device wafer 130 is bonded to the second substrate 101 through the liner oxide layer 105 by fusion bonding (oxide to silicon) without a plasma treatment. The device wafer 130 covers the cavities 103. In step S109, the device wafer 130 has a thickness T1. Then, in step S111, the device wafer 130 is thinned by grinding on its back side 130B, and a chemical-mechanical polish (CMP) process is performed on the back side of the thinned device wafer 130 to achieve a thickness T2 that is less than the thickness T1. The thickness T2 of the thinned device wafer 130 may be about 32 µm.

Next, referring to FIG. 5, in step S113, the thinned device wafer 130 is patterned by photolithography and etching processes to form multiple stand-off structures 132 integrated with a device layer 131. The stand-off structures 132 protrude from a surface of the device layer 131. The height of the stand-off structures 132 may be about 2.35 µm. Afterwards, in step S115, a second germanium (Ge) layer is conformally deposited on the device layer 131 and the stand-off structures 132, and then the second Ge layer is patterned by photolithography and etching processes to form a second bonding layer 143 on the top surface and the sidewalls of the stand-off structure 132. Thereafter, in step S117, the device layer 131 is patterned by photolithography and etching processes to form multiple MEMS devices 134. In some embodiments, the MEMS devices 134 may be gyroscopes, accelerometers, an inertial measurement unit (IMU) device, and/or other MEMS devices. Each of the MEMS devices 134 is surrounded by the stand-off structure 132 and located directly above the cavity 103.

Next, referring to FIG. 6, in step S119, a first substrate 110 such as a silicon wafer is provided with multiple CMOS transistors formed therein. An interconnect layer 120 is formed on the front side of the first substrate 110. The interconnect layer 120 includes a top metal layer 121 with a seal ring 121A. The first substrate 110 and the interconnect layer 120 together may be referred to as a CMOS/interconnect wafer. A passivation layer 126 is formed on the top metal layer 121 of the interconnect layer 120. The passivation layer 126 has an opening 125A to expose the seal ring 121A and another opening 125B to expose a bond pad 121B of the top metal layer 121. The details of the interconnect layer 120 and the passivation layer 126 may refer to the aforementioned descriptions of the MEMS package 100 in FIG. 1, and not repeated herein.

Then, still referring to FIG. 6, in step S121, a first germanium (Ge) layer 140 is conformally deposited on the interconnect layer 120 and the passivation layer 126. The first Ge layer 140 is conformally deposited on the top metal layer 121 and in the opening 125A, the opening 125B and other openings of the passivation layer 126. The thickness of the first Ge layer 140 may be about 50 nm to about 100 nm. Next, in step S123, the first Ge layer 140 is patterned by photolithography and etching processes to form a patterned first Ge layer 140 on the seal ring 121A, completely covering the portion of the seal ring 121A exposed from the opening 125A. In some embodiments, the patterned first germanium (Ge) layer 140 is formed within the opening 125A and further extends onto the passivation layer 126. In other embodiments, the patterned first germanium (Ge) layer 140 may not extend onto the passivation layer 126. Several different configurations of the patterned first Ge layer 140, the seal ring 121A, the opening 125A, and the passivation layer 126 may refer to the cross-sectional views A1, A2, A3 and A4 as shown in FIG. 2, where the arrangement of the patterned first Ge layer 140 is the same as that of the first bonding layer 141.

Next, referring to FIG. 7, in step S125, a wet pre-clean process 150 is performed on the patterned first Ge layer 140 to remove native oxide (i.e., GeO₂), on the patterned first Ge layer 140. The wet pre-clean process 150 may use deionized (DI) water or dilute hydrofluoric acid (DHF) and is a low-cost, high-throughput batch process compared to a single-wafer argon (Ar) plasma pre-clean process. Since the seal ring 121A is protected by the patterned first Ge layer 140 from native oxide growth, the interconnect layer 120 does not require an Ar plasma pre-clean process to remove native oxide on the seal ring 121A. Therefore, the interconnect layer 120 is not treated with an Ar plasma pre-clean process.

Afterwards, still referring to FIG. 7, in step S127, the structure in step S117 of FIG. 5 is inverted, and the stand-off structure 132 protrudes toward the interconnect layer 120 and the first substrate 110. Then, the device layer 131 is bonded to the interconnect layer 120 through the stand-off structure 132, the second bonding layer 143, and the patterned first Ge layer 140 on the seal ring 121A. The stand-off structure 132 is bonded to the seal ring 121A by a eutectic bonding process 152 at a bonding temperature, for example, between about 400℃ and about 450℃. During the eutectic bonding process 152, the Al of the seal ring 121A and the Ge of the patterned first Ge layer 140 forms an aluminum-germanium alloy (AlGe) on the seal ring 121A during the eutectic bonding process.

Next, referring to FIG. 8, in step S129, after the eutectic bonding process 152, a first bonding layer 141 is formed on the seal ring 121A and the passivation layer 126, and in direct contact with the second bonding layer 143. In one embodiment, the first bonding layer 141 includes a first portion 141-1 that is initially composed of Ge and then transforms into AlGe during the eutectic bonding process due to the inter-diffusion of Ge into the Al below, and a second portion 141-2 composed of Ge, as shown in the cross-sectional view A1 of FIG. 2, but not limited thereto. The other cross-sectional views A2, A3 and A4 as shown in FIG. 2 may be formed by different patterned first Ge layers 140 on the seal ring 121A in step 123 of FIG. 6. The stand-off structure 132 is bonded to the seal ring 121A through the first bonding layer 141 and the second bonding layer 143. The second bonding layer 143 is thicker than the first bonding layer 141. After the eutectic bonding process 152, the second bonding layer 143 is still composed of Ge. A eutectic bonding interface 145 is formed between the first bonding layer 141 and the second bonding layer 143. The eutectic bonding interface 145 is composed of AlGe, where the Ge merges to form an AlGe alloy during and after the eutectic bonding process. In step S129, the second substrate 101 has a thickness T3, and the first substrate 110 has a thickness T4.

Then, still referring to FIG. 8, in step S131, the first substrate 110 is thinned by grinding on its back side to achieve a thickness T6 that is less than the thickness T4. The thickness T6 is, for example, about 290 µm. Also, the second substrate 101 is thinned by grinding on its back side to achieve a thickness T5 that is less than the thickness T3. The total thickness including that of the device layer 131 and the thickness T5 of the second substrate 101 is, for example, about 210 µm.

Next, referring to FIG. 9, in step S133, the edges of the second substrate 101 are trimmed to be smaller than the second substrate 110 and the interconnect layer 120. The liner oxide layer 105 on the sidewalls of the second substrate 101 is also removed. Then, a metal layer 107 such as an Al layer is deposited on the back surface of the second substrate 101. The thickness of the metal layer 107 is, for example about 0.8 µm. Thereafter, in step S135, portions of the metal layer 107, the second substrate 101, and the device layer 131 at scribe lines SL are cut through by tab dicing with a saw blade, thereby exposing the bond pad 121B of the top metal layer 121 and a pre-cut line 128 in the passivation layer 126. Afterwards, the interconnect layer 120 and the first substrate 110 are diced along the pre-cut line 128 to complete the MEMS package 100 of FIG. 1.

According to embodiments of the present disclosure, the MEMS packages include the first bonding layer to protect the seal ring of the top metal layer in the interconnect layer from native oxide growth. Therefore, the interconnect layer of the MEMS packages does not require an Ar plasma pre-clean process on the seal ring. This avoids stiction caused by the dielectric charging effect of the Ar plasma pre-clean process. Moreover, it also avoids lowering the vacuum within the MEMS device caused by Ar plasma ions trapped in the interconnect layer and later outgassing during or after eutectic bonding of the device layer to the interconnect layer. Therefore, the performance and quality of the MEMS packages are improved.

In addition, before the eutectic bonding process, the native oxide on the deposited material of the first bonding layer is removed by a low-cost, high-throughput wet pre-clean batch process, thereby enhancing the yield of the MEMS packages. Furthermore, the eutectic bonding interface composed of AlGe and Ge between the first bonding layer and the second bonding layer helps to improve the bonding quality of the MEMS packages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a first substrate;
an interconnect layer, disposed on the first substrate and including a top metal layer with a seal ring;
a passivation layer, disposed on the top metal layer and having an opening to expose the seal ring;
a first bonding layer, disposed on the seal ring;
a device layer, including a MEMS device and disposed above the interconnect layer;
a stand-off structure, disposed under the device layer and surrounding the MEMS device;
a second bonding layer, disposed under the stand-off structure, and in direct contact with the first bonding layer; and
a second substrate, including a cavity and bonded to the device layer.

2. The MEMS package of claim 1, wherein the first bonding layer comprises a first portion in direct contact with the seal ring, a composition of the first portion comprises germanium (Ge) of the first bonding layer over aluminum (Al) of the seal ring, and a composition of the second bonding layer comprises germanium (Ge).

3. The MEMS package of claim 2, wherein the first bonding layer comprises a second portion in direct contact with the passivation layer, and a composition of the second portion comprises germanium (Ge).

4. The MEMS package of claim 1, wherein the second bonding layer is thicker than the first bonding layer.

5. The MEMS package of claim 1, wherein a eutectic bonding interface between the first bonding layer and the second bonding layer comprises an aluminum-germanium alloy (AlGe).

6. The MEMS package of claim 1, wherein a composition of the seal ring comprises aluminum (Al).

7. The MEMS package of claim 1, wherein the first bonding layer is disposed in the opening of the passivation layer and extends onto the passivation layer.

8. The MEMS package of claim 1, wherein the second bonding layer comprises a portion conformally disposed on a sidewall of the stand-off structure, the first bonding layer comprises a portion conformally disposed on a sidewall of the opening of the passivation layer, and the portion of the second bonding layer is laterally separated from the portion of the first bonding layer.

9. The MEMS package of claim 1, wherein a portion of the seal ring exposed from the opening of the passivation layer is completely covered by the first bonding layer.

10. A method of fabricating a micro-electro-mechanical system (MEMS) package, comprising:
providing a first substrate;
forming an interconnect layer on the first substrate, wherein the interconnect layer includes a top metal layer with a seal ring;
forming a passivation layer on the top metal layer, wherein the passivation layer has an opening to expose the seal ring;
forming a first bonding layer on the seal ring;
providing a second substrate;
forming a cavity in the second substrate;
forming a device layer on the second substrate to cover the cavity;
forming a stand-off structure integrated with the device layer;
forming a second bonding layer on the stand-off structure;
patterning the device layer to form a MEMS device, wherein the stand-off structure surrounds the MEMS device; and
bonding the stand-off structure to the seal ring through the first bonding layer and the second bonding layer.

11. The method of claim 10, wherein forming the first bonding layer comprises:
conformally depositing a first germanium (Ge) layer on the top metal layer, on the passivation layer, and in the opening of the passivation layer; and
patterning the first germanium (Ge) layer.

12. The method of claim 11, further comprising performing a wet pre-clean process on the first germanium (Ge) layer after the first germanium (Ge) layer is patterned and before bonding the stand-off structure to the seal ring.

13. The method of claim 12, wherein the wet pre-clean process is performed with a deionized water or a dilute hydrofluoric acid to remove a native oxide formed on the first germanium (Ge) layer.

14. The method of claim 10, wherein the interconnect layer is not treated with an argon (Ar) plasma pre-clean process.

15. The method of claim 10, wherein forming the second bonding layer comprises:
conformally depositing a second germanium (Ge) layer on the stand-off structure and the device layer before forming the MEMS device; and
patterning the second germanium (Ge) layer.

16. The method of claim 10, wherein the second bonding layer is thicker than the first bonding layer.

17. The method of claim 10, wherein a composition of the seal ring comprises aluminum (Al).

18. The method of claim 10, wherein the stand-off structure is bonded to the seal ring by an eutectic bonding process at a bonding temperature between 400℃ and 450℃.

19. The method of claim 10, wherein after the stand-off structure is bonded to the seal ring, a eutectic bonding interface is formed between the first bonding layer and the second bonding layer, and the eutectic bonding interface comprises an aluminum-germanium alloy (AlGe).

20. The method of claim 10, wherein the first bonding layer is formed in the opening of the passivation layer, completely covers a portion of the seal ring exposed from the opening of the passivation layer, and extends onto the passivation layer.
